(19) United States
(12) Patent Application Publication
(10) Pub. No.: US 2025/0115792 A1
(43) Pub. Date: Apr. 10, 2025

(54) Silver Pastes Used for Manufacturing a Printed Antenna

(71) Applicant: Henkel AG & Co. KGaA, Duesseldorf (DE)

(72) Inventors: Jing Yang, Shanghai (CN); Shawn Xun Mo, Shanghai (CN); Yue Wang, Shanghai (CN)

(21) Appl. No.: 18/989,212

(22) Filed: Dec. 20, 2024

Related U.S. Application Data
(63) Continuation of application No. PCT/CN2022/102940, filed on Jun. 30, 2022.

(51) Int. Cl. C09J 9/02; C08K 3/08; C08K 3/11; C08K 3/22; C08K 7/18; H01B 1/22; H01Q 1/38

(52) U.S. Cl. CPC C09J 9/02; H01B 1/22; H01Q 1/38; C08K 2003/0806; C08K 3/11; C08K 2003/2244; C08K 7/18; C08K 2201/001; C08K 2201/005; C08K 2201/014; C09J 2203/326; C09J 2463/00

(57) ABSTRACT

The present invention provides silver pastes used for manufacturing a printed antenna, kit-of-parts for preparing a printed antenna for an electronic device comprising three kinds of the silver pastes, use of the silver paste as a via fill ink, a method for preparing a printed antenna circuit with the three kinds of the silver pastes, a printed antenna for an electronic device obtained with the silver pastes, and an electronic device comprising the printed antenna. The silver pastes contain: 2 to 40% by weight of at least one epoxy resin; 0 to 5% by weight of at least one curing agent selected from the group consisting of an amino resin, a low-temperature cationic curing agent, an amine or imidazole capsule curing agent, and combinations thereof; 40 to 90% by weight of at least one filler mixture comprising silver flakes and silver spheres; 10 to 25% by weight of at least one diluent, or 0 to 20% by weight of at least one curing accelerator; and 0 to 5% by weight of at least one coupling agent selected from the group consisting of a silane coupling agent, a titanium-based coupling agent, an aluminum-based coupling agent, and combinations thereof, wherein all the above weight percentages are based on the total weight of the silver paste. The silver pastes of the present invention have high reliability and high conductivity, and have good weather resistance, or good wearing resistance, or no bubbles; and the combination of three kinds of the silver pastes can be excellently used for manufacturing a printed antenna.

### TECHNICAL FIELD

The present invention relates to silver pastes used for manufacturing a printed antenna. In particular, the present invention provides silver pastes used for manufacturing a printed antenna, kit-of-parts for preparing a printed antenna for an electronic device comprising three kinds of the silver pastes, use of the silver paste as a via fill ink, a method for preparing a printed antenna circuit with the three kinds of the silver pastes, a printed antenna for an electronic device obtained with the silver pastes, and an electronic device comprising the printed antenna.

### BACKGROUND OF THE INVENTION

With the 5G communication technology entering our life, there are more and more antennas in a smart phone and other smart devices. Traditional LDS and FPC technology already cannot fulfil the new requirements of antennas. A new technology PDS (Printed Direct-forming Structure) was developed as the times require. In PDS antenna, three kinds of silver pastes (Surface Conductive Ink, Touch Point Conductive Ink and Via Fill Conductive Ink) are needed to provide good conductivity and good RF performance for antenna.

As to Surface Conductive Ink, existing ones usually have a high electrical resistance, and poor aging properties. As to Touch Point Conductive Ink, existing ones usually have a high electrical resistance, and a low abrasion resistance. As to Via Fill Conductive Ink, existing one usually have a low adhesion strength, and bubbles. Moreover, usually, mismatch among Surface Conductive ink, Touch Point Conductive Ink, and Via Fill Conductive Ink happens, when they are used in one application; and such a mismatch will cause a lot of delamination issues during aging test.

In view of the above, it would be desirable to provide silver pastes used for manufacturing a printed antenna, especially those which can be used as Surface Conductive Ink, Touch Point Conductive Ink, or Via Fill Conductive Ink, which can overcome at least one of the above drawbacks in the prior art. In addition, it would be desirable to provide a combination of three kinds of silver pastes which can be used as Surface Conductive Ink, Touch Point Conductive Ink, or Via Fill Conductive Ink respectively, which can be excellently used for manufacturing a printed antenna.

### SUMMARY OF THE INVENTION

In a first aspect, the present invention provides a silver paste used for manufacturing a printed antenna, comprising:
2 to 40% by weight of at least one epoxy resin;
0 to 5% by weight of at least one curing agent selected from the group consisting of an amino resin, a low-temperature cationic curing agent, an amine or imidazole capsule curing agent, and combinations thereof;
40 to 90% by weight of at least one filler mixture comprising silver flakes and silver spheres;
10 to 25% by weight of at least one diluent, or 0 to 20% by weight of at least one curing accelerator; and
0 to 5% by weight of at least one coupling agent selected from the group consisting of a silane coupling agent, a titanium-based coupling agent, an aluminum-based coupling agent, and combinations thereof,
wherein all the above weight percentages are based on the total weight of the silver paste.

In particular, in a preferable embodiment of this aspect (hereinafter referred to as “the first embodiment”), the present invention provides a silver paste comprising:
2 to 20% by weight, preferably 2 to 8% by weight, more preferably 4 to 6% by weight of at least one epoxy resin,
0 to 5% by weight, preferably 0.1 to 3% by weight, more preferably 0.2 to 2% by weight of at least one curing agent, which contains an amino resin,
40 to 90% by weight, preferably 50 to 85% by weight, more preferably 70 to 80% by weight of at least one filler mixture, comprising 1 to 40% by weight of silver flakes having a tap density of from higher than 2 to 7 g/cm³, 35 to 88% by weight of silver spheres having a tap density of 5 to 7 g/cm³, and 0.08 to 0.45% by weight of zirconium hydroxide,
5 to 25% by weight, preferably 10 to 23% by weight, more preferably 15 to 20% by weight of at least one diluent,
0 to 5% by weight, preferably 0.3 to 3% by weight, more preferably 1.0 to 2.0% by weight of at least one coupling agent selected from the group consisting of a silane coupling agent, a titanium-based coupling agent, an aluminum-based coupling agent, and combinations thereof,
wherein all the above weight percentages are based on the total weight of the silver paste.

In another preferable embodiment of this aspect (hereinafter referred to as “the second embodiment”), the present invention provides a silver paste comprising:
2 to 20% by weight, preferably 2 to 8% by weight, more preferably 4 to 6% by weight of at least one epoxy resin,
0.1 to 5% by weight, preferably 0.1 to 3% by weight, more preferably 0.2 to 2% by weight of at least one curing agent, which contains an amino resin,
40 to 90% by weight, preferably 50 to 85% by weight, more preferably 70 to 80% by weight of at least one filler mixture, which contains 1 to 30% by weight of silver flakes having a tap density of from higher than 2 to 7 g/cm³, 25 to 75% by weight of silver spheres having a tap density of 5 to 7 g/cm³, 10 to 40% by weight of a wear-resistant powder having a particle size of 3.5 to 10 μm, and 0.08 to 0.45% by weight of zirconium hydroxide,
5 to 25% by weight, preferably 10 to 23% by weight, more preferably 15 to 20% by weight of at least one diluent,
0 to 5% by weight, preferably 0.3 to 3% by weight, more preferably 1.0 to 2.0% by weight of at least one coupling agent selected from the group consisting of a silane coupling agent, a titanium-based coupling agent, an aluminum-based coupling agent, and combinations thereof,
wherein all the above weight percentages are based on the total weight of the silver paste.

In a further preferable embodiment of this aspect (hereinafter referred to as “the third embodiment”), the present invention provides a silver paste comprising:
10 to 40% by weight, preferably 11 to 30% by weight, more preferably 12% to 20% by weight of at least one epoxy resin,
0.1 to 3% by weight, preferably 0.2 to 2% by weight, more preferably 0.3 to 1% by weight of at least one curing agent, which contains a low-temperature cationic curing agent or an amine or imidazole capsule curing agent,
50 to 90% by weight, preferably 60 to 88% by weight, more preferably 75 to 85% by weight of at least one filler mixture, which contains 45 to 89% by weight of silver flakes having a tap density of from higher than 2 to 7 g/cm³, and 1 to 45% of silver spheres having a tap density of 5 to 7 g/cm³,
1 to 20% by weight, preferably 2 to 15% by weight, more preferably 3 to 10% by weight of at least one curing accelerator,
0 to 5% by weight, preferably 0.3 to 3% by weight, more preferably 1.0 to 2.0% by weight of at least one coupling agent selected from the group consisting of a silane coupling agent, a titanium-based coupling agent, an aluminum-based coupling agent, and combinations thereof,
wherein all the above weight percentages are based on the total weight of the silver paste.

In a second aspect, the present invention provides kit-of-parts for preparing a printed antenna for an electronic device, comprising separately packaged
a first container comprising the silver paste according to the first embodiment,
a second container comprising the silver paste according to the second embodiment, and
a third container comprising the silver paste according to the third embodiment.

In a third aspect, the present invention provides use of the silver paste according to the third embodiment as a via fill ink for conductive connection between a surface silver paste and a touch point silver paste.

In a fourth aspect, the present invention provides a method for preparing a printed antenna circuit with the silver paste according to the first embodiment, the silver paste according to the second embodiment, and the silver paste according to the third embodiment.

In a fifth aspect, the present invention provides a printed antenna for an electronic device obtained with the silver paste according to the present invention.

In a sixth aspect, the present invention provides an electronic device comprising the printed antenna according to the present invention.

The silver paste according to the present invention can provide a very low electrical resistance (having a sheet resistance of lower than 10 mohm/square), a high adhesion, and good aging properties; or the silver paste according to the present invention can provide a high wearing resistance up to 3000 cycles, and a low electrical resistance; or the silver paste according to the present invention can provide a high strength and have no bubbles. The kit-of-parts for preparing a printed antenna for an electronic device according to the present invention do not have a mismatch problem.

### DETAILED DESCRIPTION OF THE INVENTION

It is to be understood by one of ordinary skill in the art that the present discussion is a description of exemplary embodiments only and is not intended as limiting the broader aspects of the present invention. Each aspect so described may be combined with any other aspect or aspects unless clearly indicated to the contrary. In particular, any feature indicated as being preferred or advantageous may be combined with any other feature or features indicated as being preferred or advantageous.

Unless specified otherwise, in the context of the present invention, the terms used are to be construed in accordance with the following definitions.

Unless specified otherwise, as used herein, the singular forms “a”, “an” and “the” include both singular and plural referents.

The terms “comprising” and “comprises” as used herein are synonymous with “including”, “includes” or “containing”, “contains”, and are inclusive or open-ended and do not exclude additional, non-recited members, elements or process steps.

The term “at least one” used herein to define a component refers to the type of the component, and not to the absolute number of molecules. For example, “at least one epoxy resin” means one type of epoxy resin or a mixture of a plurality of different epoxy resins.

All the tap density data used herein is determined in accordance with ISO 3953:1993. The principle of the method specified is tapping a specified amount of powder in a container by means of a tapping apparatus until no further decrease in the volume of the powder takes place. The mass of the powder divided by its volume after the test gives its tap density.

All the particle size data used herein refer to “D50 particle size” which represents a median diameter in a volume-basis particle size distribution curve obtained by measurement with a laser diffraction particle size analyzer. In this technique, the size of particles in suspensions or emulsions is measured using the diffraction of a laser beam, based on application of either Fraunhofer or Mie theory. In the present invention, Mie theory or a modified Mie theory for non-spherical particles is applied and the average particle sizes or D50 values relate to scattering measurements at an angle from 0.02 to 135 degrees relative to the incident laser beam.

Unless specified otherwise, the recitation of numerical end points includes all numbers and fractions subsumed within the respective ranges, as well as the recited end points.

Unless otherwise defined, all terms used in the disclosing the invention, including technical and scientific terms, have the meaning as commonly understood by one of the ordinary skill in the art to which this invention belongs.

In one aspect, the present disclosure is generally directed to a silver paste used for manufacturing a printed antenna, comprising:
2 to 40% by weight of at least one epoxy resin;
0 to 5% by weight of at least one curing agent selected from the group consisting of an amino resin, a low-temperature cationic curing agent, an amine or imidazole capsule curing agent, and combinations thereof;
40 to 90% by weight of at least one filler mixture comprising silver flakes and silver spheres;
10 to 25% by weight of at least one diluent, or 0 to 20% by weight of at least one curing accelerator; and
0 to 5% by weight of at least one coupling agent selected from the group consisting of a silane coupling agent, a titanium-based coupling agent, an aluminum-based coupling agent, and combinations thereof,
wherein all the above weight percentages are based on the total weight of the silver paste.

### The First Embodiment

In the first embodiment of the present invention, the silver paste contains:
2 to 20% by weight, preferably 2 to 8% by weight, more preferably 4 to 6% by weight of at least one epoxy resin,
0 to 5% by weight, preferably 0.1 to 3% by weight, more preferably 0.2 to 2% by weight of at least one curing agent, which contains an amino resin,
40 to 90% by weight, preferably 50 to 85% by weight, more preferably 70 to 80% by weight of at least one filler mixture, comprising 1 to 40% by weight of silver flakes having a tap density of from higher than 2 to 7 g/cm³, 35 to 88% by weight of silver spheres having a tap density of 5 to 7 g/cm³, and 0.08 to 0.45% by weight of zirconium hydroxide,
5 to 25% by weight, preferably 10 to 23% by weight, more preferably 15 to 20% by weight of at least one diluent,
0 to 5% by weight, preferably 0.3 to 3% by weight, more preferably 1.0 to 2.0% by weight of at least one coupling agent selected from the group consisting of a silane coupling agent, a titanium-based coupling agent, an aluminum-based coupling agent, and combinations thereof,
wherein all the above weight percentages are based on the total weight of the silver paste.

In the first embodiment of the present invention, preferably, the epoxy resin is selected from the group consisting of bisphenol-A resin, bisphenol-F resin and cycloaliphatic epoxy resin; is preferably selected from the group consisting of bisphenol-A resin and bisphenol-F resin; and more preferably is bisphenol-A resin.

Alternatively, or additionally, in the first embodiment of the present invention, preferably, the amino resin is catalyzed by a benzene sulfonic acid, wherein the amino resin is preferably selected from the group consisting of urea formaldehyde resin, melamine formaldehyde resin, and polyamide polyamine epichlorohydrins, more preferably selected from the group consisting of melamine formaldehyde resin; and/or the benzene sulfonic acid is used in the form of pyridinium p-toluenesulfonate.

Alternatively or additionally, in the first embodiment of the present invention, preferably, the filler mixture contains 2 to 35% by weight, preferably 10 to 30% by weight, more preferably 12 to 20% by weight of the silver flakes, based on the total weight of the silver paste; and/or the filler mixture contains 40 to 80% by weight, preferably 50 to 70% by weight, more preferably 55 to 65% by weight of the silver spheres, based on the total weight of the silver paste; and/or the filler mixture contains 0.1 to 0.3% by weight, preferably 0.15 to 0.25% by weight of zirconium hydroxide, based on the total weight of the silver paste; and/or the silver flakes have a particle size of 5 to 8 μm; and/or the silver flakes have a tap density of 3 to 6 g/cm³, preferably a tap density of 3.5 to 5 g/cm³; and/or the silver spheres have a particle size of 0.2 to 5 μm, preferably a particle size of 0.5 to 2 μm; and/or the silver spheres have a tap density of 5.5 to 6.5 g/cm³.

Alternatively, or additionally, in the first embodiment of the present invention, preferably, the diluent is selected from the group consisting of ketones and esters; preferably selected from the group consisting of isophorone, acetylacetone, cyclohexyl acetate, ethylene glycol butyl ether acetate, and propylene glycol methyl ether acetate; and is a mixture of isophorone, acetylacetone, cyclohexyl acetate, ethylene glycol butyl ether acetate, and propylene glycol methyl ether acetate.

The silver paste according to the first embodiment can provide a very low electrical resistance (having a sheet resistance of lower than 10 mohm/square), a high adhesion, and good aging properties; and thus, can be successfully used as Surface Conductive Ink.

### The Second Embodiment

In the second embodiment of the present invention, the silver paste contains:
2 to 20% by weight, preferably 2 to 8% by weight, more preferably 4 to 6% by weight of at least one epoxy resin,
0.1 to 5% by weight, preferably 0.1 to 3% by weight, more preferably 0.2 to 2% by weight of at least one curing agent, which contains an amino resin,
40 to 90% by weight, preferably 50 to 85% by weight, more preferably 70 to 80% by weight of at least one filler mixture, which contains 1 to 30% by weight of silver flakes having a tap density of from higher than 2 to 7 g/cm³, 25 to 75% by weight of silver spheres having a tap density of 5 to 7 g/cm³, 10 to 40% by weight of a wear-resistant powder having a particle size of 3.5 to 10 μm, and 0.08 to 0.45% by weight of zirconium hydroxide,
5 to 25% by weight, preferably 10 to 23% by weight, more preferably 15 to 20% by weight of at least one diluent,
0 to 5% by weight, preferably 0.3 to 3% by weight, more preferably 1.0 to 2.0% by weight of at least one coupling agent selected from the group consisting of a silane coupling agent, a titanium-based coupling agent, an aluminum-based coupling agent, and combinations thereof,
wherein all the above weight percentages are based on the total weight of the silver paste.

In the second embodiment of the present invention, preferably, the epoxy resin is selected from the group consisting of bisphenol-A resin, bisphenol-F resin and cycloaliphatic epoxy resin; is preferably selected from the group consisting of bisphenol-A resin and bisphenol-F resin; and more preferably is bisphenol-A resin.

Alternatively, or additionally, in the second embodiment of the present invention, preferably, the amino resin is catalyzed by a benzene sulfonic acid, wherein the amino resin is preferably selected from the group consisting of urea formaldehyde resin, melamine formaldehyde resin, and polyamide polyamine epichlorohydrins, more preferably selected from the group consisting of melamine formaldehyde resin; and/or the benzene sulfonic acid is used in the form of pyridinium p-toluenesulfonate.

Alternatively or additionally, in the second embodiment of the present invention, preferably, the filler mixture contains 2 to 25% by weight, preferably 3 to 10% by weight, more preferably 4 to 8% by weight of the silver flakes, based on the total weight of the silver paste; and/or the filler mixture contains 30 to 70% by weight, preferably 40 to 60% by weight, more preferably 45 to 55% by weight of the silver spheres, based on the total weight of the silver paste; and/or the filler mixture contains 12 to 30% by weight, preferably 18 to 25% by weight of the wear-resistant powder, based on the total weight of the silver paste; and/or the filler mixture contains 0.1 to 0.3% by weight, preferably 0.15 to 0.25% by weight of zirconium hydroxide, based on the total weight of the silver paste.

Alternatively or additionally, in the second embodiment of the present invention, preferably, the silver flakes have a particle size of 5 to 8 μm; and/or the silver flakes have a tap density of 3 to 6 g/cm³, preferably a tap density of 3.5 to 5 g/cm³; and/or the silver spheres have a particle size of 0.2 to 5 μm, preferably of 0.5 to 2 μm; and/or the silver spheres have a tap density of 5.5 to 6.5 g/cm³; and/or the wear-resistant powder is selected from the group consisting of silicon powder, zirconia powder, alumina powder and alloy powder, wherein the alloy powder is preferably selected from the group consisting of iron nickel alloy powder and iron manganese alloy powder, and more preferably is iron nick alloy powder; and/or the alloy powder has a particle size of 4 to 8 μm, preferably 4.5 to 7 μm.

Alternatively, or additionally, in the second embodiment of the present invention, preferably, the diluent is selected from the group consisting of ketones and esters; preferably selected from the group consisting of isophorone, acetylacetone, cyclohexyl acetate, ethylene glycol butyl ether acetate, and propylene glycol methyl ether acetate; and is a mixture of isophorone, acetylacetone, cyclohexyl acetate, ethylene glycol butyl ether acetate, and propylene glycol methyl ether acetate.

The silver paste according to the second embodiment can provide a high wearing resistance (2000 to 3000 cycles), and a relatively low electrical resistance; and thus, can be successfully used as Touch Point Conductive Ink.

### The Third Embodiment

In the third embodiment of the present invention, the silver paste contains:
10 to 40% by weight, preferably 11 to 30% by weight, more preferably 12% to 20% by weight of at least one epoxy resin,
0.1 to 3% by weight, preferably 0.2 to 2% by weight, more preferably 0.3 to 1% by weight of at least one curing agent, which contains a low-temperature cationic curing agent or an amine or imidazole capsule curing agent,
50 to 90% by weight, preferably 60 to 88% by weight, more preferably 75 to 85% by weight of at least one filler mixture, which contains 45 to 89% by weight of silver flakes having a tap density of from higher than 2 to 7 g/cm³, and 1 to 45% of silver spheres having a tap density of 5 to 7 g/cm³,
1 to 20% by weight, preferably 2 to 15% by weight, more preferably 3 to 10% by weight of at least one curing accelerator,
0 to 5% by weight, preferably 0.3 to 3% by weight, more preferably 1.0 to 2.0% by weight of at least one coupling agent selected from the group consisting of a silane coupling agent, a titanium-based coupling agent, an aluminum-based coupling agent, and combinations thereof,
wherein all the above weight percentages are based on the total weight of the silver paste.

In the third embodiment of the present invention, preferably, the epoxy resin is selected from the group consisting of bisphenol-A resin, bisphenol-F resin and cycloaliphatic epoxy resin; is preferably selected from the group consisting of bisphenol-F resin and a cycloaliphatic epoxy resin; and more preferably is the combination of bisphenol-F resin and a cycloaliphatic epoxy resin.

Alternatively, or additionally, in the third embodiment of the present invention, preferably, the low-temperature cationic curing agent is cured at a temperature of 60 to 90° C., preferably at a temperature of 70 to 80° C.; and/or the low-temperature cationic curing agent is hexafluoroantimonate and/or hexafluorophosphate, and preferably is hexafluoroantimonate; and/or the amine or imidazole capsule curing agent is an imidazole capsule curing agent.

Alternatively or additionally, in the third embodiment of the present invention, preferably, the filler mixture contains 50 to 85% by weight, preferably 60 to 80% by weight, more preferably 65 to 75% by weight of the silver flakes, based on the total weight of the silver paste; and/or the filler mixture contains 2 to 35% by weight, preferably 5 to 20% by weight, more preferably 8 to 15% by weight of the silver spheres, based on the total weight of the silver paste; and/or the silver flakes have a particle size of 5 to 20 μm; and/or the silver spheres have a particle size of 5 to 20 μm; and/or the silver flakes have a tap density of 3 to 6 g/cm³, preferably a tap density of 3.5 to 5 g/cm³; and/or the silver spheres have a tap density of 5.5 to 6.5 g/cm³.

Alternatively, or additionally, in the third embodiment of the present invention, preferably, the curing accelerator is selected from the group consisting of oxetanes, and preferably is (3-ethyl-3-oxetanyl) methanol.

The silver paste according to the third embodiment can provide a high strength and have no bubbles; and thus, can be successfully used as Via Fill Conductive Ink.

The method for preparing the silver paste according to the present invention can be any conventional method for preparing silver paste, and is not specifically limited, as long as such a silver paste can be obtained. For example, the method for preparing the silver paste may comprise: stirring at least one epoxy resin and optional at least one diluent, adding at least one filler mixture and stirring the mixture thus obtained, adding optional at least one curing agent and at least one coupling agent and stirring the mixture thus obtained, and then three-roll grinding the mixture obtained above.

In another aspect, the present disclosure is directed to kit-of-parts for preparing a printed antenna for an electronic device, comprising separated packaged
a first container comprising the silver paste according to the first embodiment,
a second container comprising the silver paste according to the second embodiment, and
a third container comprising the silver paste according to the third embodiment.

The combination of the three kinds of silver paste does not have a mismatch problem and has good aging properties.

In yet another aspect, the present disclosure is directed to use of the silver paste according to the third embodiment as Via Fill Ink for conductive connection between for conductive connection between Surface silver paste and Touch point silver paste, preferably conductive connection between the silver paste according to the first embodiment and the silver paste according to the second embodiment.

In yet another aspect, the present disclosure is directed to a method for preparing a printed antenna circuit, comprising the steps of:
i) applying the silver paste according to the third embodiment into a via in a middle frame of a mobile phone with a glue dispenser, and then curing it at 80 to 90° C. for 0.5 to 2 hours, preferably for 0.8 to 1.5 hours, more preferably for about 1 hour, and dwelling for 0.5 to 2 hours, to obtain a product;
ii) applying the silver paste according to the first embodiment to the product obtained in step i) with a pad printer for three times, and then curing it at 80 to 90° C. for 0.5 to 2 hours, preferably for 0.8 to 1.5 hours, more preferably for about 1 hour, to obtain a Ag film having a thickness of 10 to 20 μm, preferably about 15 μm; and
iii) applying the silver paste according to the second embodiment to the Ag film obtained in step ii) with a pad printer for five times and curing it at 80 to 90° C. for 1 to 3 hours, preferably for 1.5 to 2.5 hours, more preferably for about 2 hours, to obtain the printed antenna circuit.

Preferably, the middle frame of the mobile phone is made from PC, LPA, aluminum alloy, ceramic, glass and/or magnesium alloy.

In a further aspect, the present invention also provides a printed antenna for an electronic device, obtained with the silver paste according to the present invention, preferably with the silver paste according to the first embodiment, the silver paste according to the second embodiment, and/or the silver paste according to the third embodiment, more preferably with the kit-of-parts according to the present invention.

In a furthermore aspect, the present invention provides an electronic device comprising the printed antenna according to the present invention.

With regard to the further preferred embodiment of kit-of-parts, use of the silver pastes according to the third embodiment, method for preparing a printed antenna circuit, a printed antenna for an electronic device, and an electric device comprising the printed antenna, what has been said about the silver pastes applies mutatis mutandis.

### EXAMPLES

The present invention will be further described and illustrated in detail with reference to the following examples. The examples are intended to assist one skilled in the art to better understand and practice the present invention, however, are not intended to restrict the scope of the present invention. All the amounts in the examples are based on weight in grams unless otherwise stated.

### Materials

The following materials were employed in the Examples:

| Type | Trade Name | Name | Manufacturer |
|---|---|---|---|
| Resin | OXT 506 | Bisphenol A epoxy resin | Precise Chem |
| Resin | Celloxide 2021 | Bisphenol F epoxy resin and | Daicel Chemical |
| | P:DER332 = | Cycloaliphatic epoxy resin | Industries, and Olin |
| | 1:1 by weight | | |
| Curing agent | AM345 | Modified melamine | Precise Chem |
| | | formaldehyde resin catalyzed | |
| | | by a benzene sulfonic acid (in | |
| | | the form of pyridinium p- | |
| | | toluenesulfonate) | |
| Filler | ANAE104 | Silver Flake 1 (tap density: 3.9 | Runqin Electronics |
| | | g/cm³) | |
| Filler | ANAE 108 | Silver Flake 2 (tap density: 2.0 | Runqin Electronics |
| | | g/cm³) | |
| Filler | ANAE101 | Silver Sphere 1 (tap density: | Runqin Electronics |
| | | 6.0 g/cm³) | |
| Filler | ANAE107 | Silver Sphere 2 (tap density: | Runqin Electronics |
| | | 4.0 g/cm³) | |
| Filler | ANAE105 | Iron Nickel Alloy 1 powder | Runqin Electronics |
| | | (average particle size: 5 μm) | |
| Filler | ANAE102 | Iron Nickel Alloy powder 2 | Runqin Electronics |
| | | (average particle size: 2 μm) | |
| Filler | | Zirconium hydroxide | Beijing |
| | | | Juguangyingchuang |
| | | | Technology Co., Ltd. |
| Curing agent | K Pure CXC | Antimony hexafluoride | King Industries |
| | 1612 | | |
| Curing accelerator | OXT 301 | (3-ethyl-3-oxetanyl)methanol | Precise Chem |
| Solvent | | isophorone | SINOPHARM |
| Solvent | | cyclohexyl acetate | SINOPHARM |
| Solvent | | ethylene glycol butyl ether | SINOPHARM |
| | | acetate | |
| Solvent | | propylene glycol methyl ether | SINOPHARM |
| | | acetate | |
| Solvent | | acetylacetone | SINOPHARM |

### Preparation of Silver Pastes

Silver pastes of Examples according to the present invention (hereinafter “EX” for short) and Comparative Examples (hereinafter “CE” for short) were prepared according to the compositions as recorded in Table 1 as follows: the epoxy resin(s) and the optional diluents were stirred to be homogeneous; the filler mixture was added and the mixture thus obtained was stirred to be homogeneous; the optional curing agent or the curing accelerator was added and the mixture thus obtained was stirred to be homogeneous; and then the mixture obtained above was three-roll grinded.

### Test Methods

The properties of the silver pastes of Examples and Comparative Examples were measured according to the following methods.

### Sheet Resistance of the Silver Pastes

The silver pastes of Examples and Comparative Examples were coated with a gap of 2 mils onto a Mylar substrate. The samples were cured at 80 to 90° C. for 1 hour. A 2-point probe measurement was performed as follows: lines of about 100 mm length and about 2 mm width were cut into the film to test. Resistance was measured with a multimeter. Thickness of the line coating was measured with in several places on the line and an average thickness was calculated. The sheet resistance is given by the following formula:

$$Sheet resistance [ \frac{\frac{Ω}{square}}{mil} ] = \frac{Resistance [ Ω ] * Thickness [ mils ]}{square snumber [ dimentionless ]}$$

$$wherein , squares number = \frac{Length [ mm ]}{Width [ mm ]}$$

The sheet resistance was specific to the silver paste when cured. The lower the sheet resistance value, the better the conductivity. The first embodiment of the silver past having a sheet resistance of lower than 10 mohm/square is acceptable; the second embodiment of silver past having a sheet resistance of no more than 30 mohm/square is acceptable; and the third embodiment of silver past having a sheet resistance of lower than 80 mohm/square is acceptable.

### Adhesion of the Silver Pastes

The adhesion of the silver pastes was tested as follows: 1) using a sharp blade to draw in a specified area 10×10 1 mm*1 mm, wherein each line must penetrate the ink to the end of the material; 2) brushing the surface with dustless cloth or brush, sticking small mesh with 3M 610 tape and pressing flat, extruding bubble, static pressure for more than 5 minutes, keeping the product still, pulling up the tape side at 90 degrees angle quickly.

The adhesion of the silver pastes used for manufacturing a printed antenna should be at least 4B (silver layer is peeled off less than 5% and cohesion failure with silver is not allowed).

### Adhesion-Artificial Sweat of the Silver Pastes

Adhesion-Artificial sweat test of the silver pastes was tested as follows: dipping the wiper into PH4.6 artificial sweat, putting it on the silver paste sample, then putting them into a seal bag, and storing it under the condition 65±1° C./91-95% RH for 48 hours, and then conducting the adhesion test as above.

The Adhesion-Artificial sweat of silver pastes used for manufacturing a printed antenna should be at least 4B.

### Adhesion-Boiling of the Silver Pastes

Adhesion-Boiling t of the silver pastes was tested as follows: boiling the silver paste sample for 30 minutes and 2 hours, during which the sample cannot contact the wall of container; taking out and thawing the sample at room temperature for at least two hours; and then conducing the adhesion test as above.

The Adhesion-Boiling of the silver pastes used for manufacturing a printed antenna should be at least 4B.

### RCA Wearing Resistance of the Silver Pastes

RCA wearing resistance (175 g) of the silver pastes was tested as follows: taking a silver paste sample and applying it 175 g load, conducting wearing with 2000 cycles, checking appearance and testing performance, in which the RCA abrader (type: 7-IBB-CC) used was obtained from Norman tool.

The RCA wearing resistance (175 g) of the silver pastes used for manufacturing a printed antenna should not expose substrate.

### Via Hole Cross-Section of the Silver Pastes

Via hole cross-section of the silver pastes was tested as follows: filling the hole with glue and taking 2 pcs of silver paste product to do cross-section.

The via hole cross-section result of the silver pastes used for manufacturing a printed antenna should have no bubbles with diameters of more than 0.5 mm in the narrowest area.

The results of the above tests of the silver pastes were also listed in Table 1.

### The Impedance Test of the Printed Antenna Prepared by the Silver Pastes

The antenna fabricated by the silver pastes of Examples and Comparative Examples was prepared in the following steps:
i) applying the silver pastes of the third embodiment into a via in a middle frame of a mobile phone with a glue dispenser, and then curing it at 80° C. for 2 hours, and dwelling for 1 hour, to obtain a product;
ii) applying the silver pastes of the first embodiment to the product obtained in step i) with a pad printer for three times, and then curing it at 80° C. for 2 hours, to obtain a Ag film having a thickness of 15 μm; and
iii) applying the silver pastes of the second embodiment to the Ag film obtained in step ii) with a pad printer for five times, and curing it at 80° C. for 2 hours, to obtain the printed antenna circuit.

The specific combinations of the first embodiment, the second embodiment and the third embodiment of the silver pastes were listed in Table 2.

The impedance of the printed antenna circuit of each combination was measured by applying at the antenna terminals with an amplitude of 1 volt and measuring the electric current. The impedance was calculated by the following formula:

$$Impedance [ Ω ] = \frac{Voltage [ volt ]}{Electric current [ Amps ]}$$

The impedance of the antenna circuit of no more than 1 ohm is acceptable and recorded as “Pass”, while the resistance of larger than 1 ohm was recorded as “Not Pass”; and the results of the combinations were also listed in Table 2.

TABLE 1

| | The first | | | | | | | | | |
|---|---|---|---|---|---|---|---|---|---|---|
| | embodiment of | | | The second embodiment of | | | | The third embodiment of silver | | |
| | silver paste | | | silver paste | | | | paste | | |
| | EX1 | CE1 | CE2 | EX2 | CE3 | CE4 | CE5 | EX3 | CE6 | CE7 |
| Components | | | | | | | | | | |
| (weight, in | | | | | | | | | | |
| gram) | | | | | | | | | | |
| Bisphenol A | 5 | 5 | 5 | 5 | 5 | 5 | 5 | 0 | 0 | 0 |
| epoxy resin | | | | | | | | | | |
| Bisphenol F | 0 | 0 | 0 | 0 | 0 | 0 | 0 | 14.5 | 14.5 | 19.5 |
| epoxy resin | | | | | | | | | | |
| and | | | | | | | | | | |
| Cycloaliphatic | | | | | | | | | | |
| epoxy resin | | | | | | | | | | |
| Modified | 0.3 | 0.3 | 0.3 | 0.3 | 0.3 | 0.3 | 0 | 0 | 0 | 0 |
| melamine | | | | | | | | | | |
| formaldehyde | | | | | | | | | | |
| resin | | | | | | | | | | |
| catalyzed by | | | | | | | | | | |
| a benzene | | | | | | | | | | |
| sulfonic acid | | | | | | | | | | |
| (in the form of | | | | | | | | | | |
| pyridinium p- | | | | | | | | | | |
| toluenesulfonate) | | | | | | | | | | |
| Antimony | 0 | 0 | 0 | 0 | 0 | 0 | 0 | 0.5 | 0.5 | 0.5 |
| hexafluoride | | | | | | | | | | |
| Silver Flake 1 | 15 | 0 | 15 | 5 | 5 | 5 | 5 | 70 | 0 | 70 |
| (tap density: | | | | | | | | | | |
| 3.9 g/cm³) | | | | | | | | | | |
| Silver Flake 2 | 0 | 15 | 0 | 0 | 0 | 0 | 0 | 0 | 70 | 0 |
| (tap density: | | | | | | | | | | |
| 2.0 g/cm³) | | | | | | | | | | |
| Silver Sphere | 60 | 60 | 0 | 50 | 60 | 50 | 50 | 10 | 10 | 10 |
| 1 (tap density: | | | | | | | | | | |
| 6.0 g/cm³) | | | | | | | | | | |
| Silver Sphere | 0 | 0 | 60 | 0 | 0 | 0 | 0 | 0 | 0 | 0 |
| 2 (tap density: | | | | | | | | | | |
| 4.0 g/cm³) | | | | | | | | | | |
| Iron Nickel | 0 | 0 | 0 | 20 | 10 | 0 | 20 | 0 | 0 | 0 |
| Alloy Powder | | | | | | | | | | |
| 1 (average | | | | | | | | | | |
| particle size: | | | | | | | | | | |
| 5 μm) | | | | | | | | | | |
| Iron Nickel | 0 | 0 | 0 | 0 | 0 | 20 | 0 | 0 | 0 | 0 |
| Alloy Powder | | | | | | | | | | |
| 2 (average | | | | | | | | | | |
| particle size: | | | | | | | | | | |
| 2 μm) | | | | | | | | | | |
| (3-ethyl-3- | 0 | 0 | 0 | 0 | 0 | 0 | 0 | 5 | 5 | 0 |
| oxetanyl)methanol | | | | | | | | | | |
| isophorone | 4 | 4 | 4 | 5 | 4 | 4 | 4 | 0 | 0 | 0 |
| acetylacetone | 0.6 | 0.6 | 0.6 | 0.6 | 0.6 | 0.6 | 0.6 | 0 | 0 | 0 |
| cyclohexyl | 2.9 | 2.9 | 2.9 | 2.9 | 2.9 | 2.9 | 3.2 | 0 | 0 | 0 |
| acetate | | | | | | | | | | |
| ethylene | 8 | 8 | 8 | 8 | 8 | 8 | 8 | 0 | 0 | 0 |
| glycol butyl | | | | | | | | | | |
| ether acetate | | | | | | | | | | |
| propylene | 4 | 4 | 4 | 4 | 4 | 4 | 4 | 0 | 0 | 0 |
| glycol methyl | | | | | | | | | | |
| ether acetate | | | | | | | | | | |
| Zirconium | 0.2 | 0.2 | 0.2 | 0.2 | 0.2 | 0.2 | 0.2 | 0 | 0 | 0 |
| hydroxide | | | | | | | | | | |
| Testing result | | | | | | | | | | |
| Sheet | 6 | 7 | 20 | 30 | 25 | 30 | 30 | 40 | 60 | 80 |
| Resistance | | | | | | | | | | |
| (mohm/ | | | | | | | | | | |
| square) | | | | | | | | | | |
| Adhesion- | 4B | 2B | 4B | 4B | 4B | 4B | 4B | 4B | 4B | 4B |
| Artificial | | | | | | | | | | |
| sweat | | | | | | | | | | |
| Adhesion- | 5B | 2B | 4B | 5B | 5B | 5B | 5B | 4B | 5B | 3B |
| Boiling test | | | | | | | | | | |
| RCA wearing | N/A | N/A | N/A | >3000 | 1000 | 800 | 500 | N/A | N/A | N/A |
| resistance | | | | | | | | | | |
| (175 g) | | | | | | | | | | |
| (Number of | | | | | | | | | | |
| cycles) | | | | | | | | | | |
| Via hole | N/A | N/A | N/A | N/A | N/A | N/A | N/A | No | Have | Have |
| cross-section | | | | | | | | bubbles | bubble | bubble |
| result | | | | | | | | | with | with |
| | | | | | | | | | diameter | diameter |
| | | | | | | | | | of more | of more |
| | | | | | | | | | than 0.5 | than 0.5 |
| | | | | | | | | | mm | mm |

TABLE 2

| | The first | | | | | | | The third | | | |
|---|---|---|---|---|---|---|---|---|---|---|---|
| | embodiment of | | | The second embodiment | | | | embodiment of | | | |
| | silver paste | | | of silver paste | | | | silver paste | | | Impedance |
| Combinations | EX1 | CE1 | CE2 | EX2 | CE3 | CE4 | CE5 | EX3 | CE6 | CE7 | Test Result |

| | | | | | | | | | | |
|---|---|---|---|---|---|---|---|---|---|---|
| Antenna | ✓ | | | ✓ | | | ✓ | | | Pass |
| circuit #1 | | | | | | | | | | |
| Antenna | ✓ | | | ✓ | | | | ✓ | | Not Pass |
| circuit #2 | | | | | | | | | | |
| Antenna | ✓ | | | | | ✓ | ✓ | | | Not Pass |
| circuit #3 | | | | | | | | | | |
| Antenna | | ✓ | | ✓ | | | ✓ | | | Not Pass |
| circuit #4 | | | | | | | | | | |
| Antenna | | | ✓ | | ✓ | | ✓ | | | Not Pass |
| circuit #5 | | | | | | | | | | |
| Antenna | | | ✓ | ✓ | | | | ✓ | | Not Pass |
| circuit #6 | | | | | | | | | | |
| Antenna | ✓ | | | | ✓ | | | | ✓ | Not Pass |
| circuit #7 | | | | | | | | | | |

From the above tables, it can be seen that the silver paste according to the first embodiment has a very low electrical resistance (having a sheet resistance of lower than 10 mohm/square), a high adhesion, and good aging properties; and thus, can be successfully used as Surface Conductive Ink; the silver paste according to the second embodiment has a high wearing resistance (>3000 cycles), and a low electrical resistance; and thus, can be successfully used as Touch Point Conductive Ink; and the silver paste according to the third embodiment has a high strength and has no bubbles; and thus, can be successfully used as Via Fill Conductive Ink. In addition, the antenna circuit prepared by the combination of the three kind of silver pastes according to the present invention shows satisfactory impedance, which is suitable for electronic applications; while the antenna circuit prepared by other combinations of silver pastes have mismatch problems, thus exhibiting inapplicable impedance.

Although some preferred embodiments have been described, many modifications and variations may be made thereto in light of the above teachings. It is therefore to be understood that the invention may be practiced otherwise than as specifically described without departing from the scope of the appended claims.

What is claimed is:

1. A silver paste used for manufacturing a printed antenna, comprising:
2 to 40% by weight of at least one epoxy resin;
0 to 5% by weight of at least one curing agent selected from the group consisting of an amino resin, a low-temperature cationic curing agent, an amine or imidazole capsule curing agent, and combinations thereof;
40 to 90% by weight of at least one filler mixture comprising silver flakes and silver spheres;
10 to 25% by weight of at least one diluent, or 0 to 20% by weight of at least one curing accelerator; and
0 to 5% by weight of at least one coupling agent selected from the group consisting of a silane coupling agent, a titanium-based coupling agent, an aluminum-based coupling agent, and combinations thereof,
wherein all the above weight percentages are based on the total weight of the silver paste.

2. The silver paste according to claim 1, comprising:
2 to 20% by weight of at least one epoxy resin,
0 to 5% by weight of at least one curing agent, which contains an amino resin,
40 to 90% by weight of at least one filler mixture, comprising 1 to 40% by weight of silver flakes having a tap density of from higher than 2 to 7 g/cm³, 35 to 88% by weight of silver spheres having a tap density of 5 to 7 g/cm³, and 0.08 to 0.45% by weight of zirconium hydroxide,
5 to 25% by weight of at least one diluent,
0 to 5% by weight of at least one coupling agent selected from the group consisting of a silane coupling agent, a titanium-based coupling agent, an aluminum-based coupling agent, and combinations thereof,
wherein all the above weight percentages are based on the total weight of the silver paste.

3. The silver paste according to claim 1, comprising:
2 to 20% by weight of at least one epoxy resin,
0.1 to 5% by weight of at least one curing agent, which contains an amino resin,
40 to 90% by weight of at least one filler mixture which contains 1 to 30% by weight of silver flakes having a tap density of from higher than 2 to 7 g/cm³, 25 to 75% by weight of silver spheres having a tap density of 5 to 7 g/cm³, 10 to 40% by weight of a wear-resistant powder having a particle size of 3.5 to 10 μm, and 0.08 to 0.45% by weight of zirconium hydroxide,
5 to 25% by weight of at least one diluent,
0 to 5% by weight of at least one coupling agent selected from the group consisting of a silane coupling agent, a titanium-based coupling agent, an aluminum-based coupling agent, and combinations thereof,
wherein all the above weight percentages are based on the total weight of the silver paste.

4. The silver paste according to claim 1, wherein the epoxy resin is selected from the group consisting of bisphenol-A resin, bisphenol-F resin and a cycloaliphatic epoxy resin.

5. The silver paste according to claim 1, wherein the amino resin is catalyzed by a benzene sulfonic acid, wherein the amino resin is selected from the group consisting of urea formaldehyde resin, melamine formaldehyde resin, and polyamide polyamine epichlorohydrins.

6. The silver paste according to claim 2, wherein the filler mixture contains 2 to 35% by weight, of the silver flakes, based on the total weight of the silver paste; and/or the filler mixture contains 40 to 80% by weight of the silver spheres based on the total weight of the silver paste; and/or the filler mixture contains 0.1 to 0.3% by weight, of zirconium hydroxide, based on the total weight of the silver paste; and/or the silver flakes have a particle size of 5 to 8 μm; and/or the silver flakes have a tap density of 3 to 6 g/cm³ and/or the silver spheres have a particle size of 0.2 to 5 μm and/or the silver spheres have a tap density of 5.5 to 6.5 g/cm³.

7. The silver paste according to claim 3, wherein the filler mixture contains 2 to 25% by weight of the silver flakes, based on the total weight of the silver paste; and/or the filler mixture contains 30 to 70% by weight of the silver spheres, based on the total weight of the silver paste; and/or the filler mixture contains 12 to 30% by weight of the wear-resistant powder, based on the total weight of the silver paste; and/or the filler mixture contains 0.1 to 0.3% by weight of the silver paste.

8. The silver paste according to claim 3, wherein the silver flakes have a particle size of 5 to 8 μm; and/or the silver flakes have a tap density of 3 to 6 g/cm³ and/or the silver spheres have a particle size of 0.2 to 5 μm; and/or the silver spheres have a lap density of 5.5 to 6.5 g/cm³; and/or the wear-resistant powder is selected from the group consisting of silicon powder, zirconia powder, alumina powder and alloy powder.

9. The silver paste according to claim 1, wherein the diluent is selected from the group consisting of ketones and esters.

10. The silver paste according to claim 1, comprising:
10 to 40% by weight of at least one epoxy resin,
0.1 to 3% by weight of at least one curing agent, which contains a low-temperature cationic curing agent or an amine or imidazole capsule curing agent,
50 to 90% by weight of at least one filler mixture, which contains 45 to 89% by weight of silver flakes having a tap density of from higher than 2 to 7 g/cm³, and 1 to 45% of silver spheres having a tap density of 5 to 7 g/cm³,
1 to 20% by weight,
0 to 5% by weight, of at least one coupling agent selected from the group consisting of a silane coupling agent, a titanium-based coupling agent, an aluminum-based coupling agent, and combinations thereof,
wherein all the above weight percentages are based on the total weight of the silver paste.

11. The silver paste according to claim 10, wherein the epoxy resin is selected from the group consisting of bisphenol-A resin, bisphenol-F resin and a cycloaliphatic epoxy resin.

12. The silver paste according to claim 10, wherein the low-temperature cationic curing agent is cured at a temperature of 60 to 90° C.; and/or the low-temperature cationic curing agent is hexafluoroantimonate and/or hexafluorophosphate; and/or the amine or imidazole capsule curing agent is an imidazole capsule curing agent.

13. The silver paste according to claim 10, wherein the filler mixture contains 50 to 85% by weight of the silver flakes, based on the total weight of the silver paste; and/or the filler mixture contains 2 to 35% by weight of the silver spheres based on the total weight of the silver paste; and/or the silver flakes have a particle size of 5 to 20 μm; and/or the silver spheres have a particle size of 5 to 20 μm; and/or the silver flakes have a tap density of 3 to 6 g/cm³ and/or the silver spheres have a tap density of 5.5 to 6.5 g/cm³.

14. The silver paste according to claim 10, wherein the curing accelerator is an oxetane.

15. A printed antenna for an electronic device, obtained with the silver paste according to claim 1.

16. An electronic device comprising the printed antenna according to claim 15.
